(19) United States
(12) Patent Application Publication
(10) Pub. No.: US 2012/0234376 A1
(43) Pub. Date: Sep. 20, 2012

(54) WEATHERABLE LAYER FOR PHOTOVOLTAIC MODULE

(75) Inventors: Stephen Yau Sang CHENG, Hong Kong (HK); Ka-Lok LEUNG, Hong Kong (HK)

(73) Assignee: DU PONT APOLLO LTD., New Territories (HK)

(21) Appl. No.: 13/051,482

(22) Filed: Mar. 18, 2011

(51) Int. Cl. H01L 31/048

(52) U.S. Cl. 136/251

(57) ABSTRACT

The invention relates to a photovoltaic (PV) module including a weatherable layer, wherein the weatherable layer comprises an acrylic polymer. The weatherable layer endows the PV module with excellent temperature resistance, weatherability, and chemical resistance.

### FIELD OF THE INVENTION

The present invention relates to the field of photovoltaic (PV) modules. Particularly, the present invention discloses a weatherable layer for PV modules.

### BACKGROUND OF THE INVENTION

Generally, a photovoltaic (PV) module is a semiconductor device capable of converting light energy, particularly solar energy, into electric energy using a photoelectric effect. A conventional PV module mainly comprises a substrate, photovoltaic cell(s), an encapsulant, such as ethylene vinyl acetate (EVA) or polyvinyl butyral (PVB), and a back protection layer including a weatherable layer.

In most applications, PV modules are mounted in an outside location such as on a rooftop, solar farm or supporting structure designed to support one or more PV modules. Thus, the sealed PV modules must have weatherablility and can resist moisture penetration when exposed to normal outdoor conditions (e.g., humid air, rain, snow, ice). Since PV modules are expected to perform over an extended time period, such as 20 to 25 years, the ability to resist the effects of the sun, rain or wind or such moisture penetration should last for such extended time period. If moisture penetrates into the modules and to the PV cells therein, the moisture will not only have an adverse affect on the appearance of the module but, more importantly, will ultimately result in the decreased performance or, possibly, total failure of the module. Therefore, it is important for the back protection layer to form a good seal to the PV module and be made of a material that resists moisture penetration and has good weatherability.

Recently, fluorinated polymeric materials have commonly been used as the back protection layer. For example, Tedlar®, a polyvinyl fluoride (PVF) material, or other fluorinated materials are used to protect PV modules requiring service in the field exposed to weathering conditions. To reduce cost, polyethylene terephthalate (PET) is also used in combination with the fluorinated polymeric materials. For example, the PVF/PET/PVF structure, a multi-layered laminated film, is commonly used as the back protection layer in the PV cell industry.

However, the above-mentioned fluorinated polymeric materials have a high cost, as well as limited supply. Therefore, there is a need for other polymer alternatives which can be used in outdoor environments for prolonged periods of time.

### SUMMARY OF THE INVENTION

In view of the problems described above, the present invention provides a photovoltaic (PV) module comprising a weatherable layer, wherein the weatherable layer comprises an acrylic-based polymer.

### BRIEF DESCRIPTION OF THE DRAWING

FIG. 1 shows a typical layout for an amorphous silicon thin-film PV module.

FIG. 2 shows an example of the present invention that the weatherable layer is applied to an amorphous silicon thin-film PV module.

FIG. 3 shows that the aluminum foil surface is protected by acrylic coating film in Energy-dispersive X-ray spectroscopy.

FIG. 4 shows a test result of an uncoated aluminum foil surface in Energy-dispersive X-ray spectroscopy.

### DETAILED DESCRIPTION OF THE INVENTION

Features from different embodiments described below are examples of the elements recited in the claims and can be combined together into one embodiment without departing from the scope of the claims.

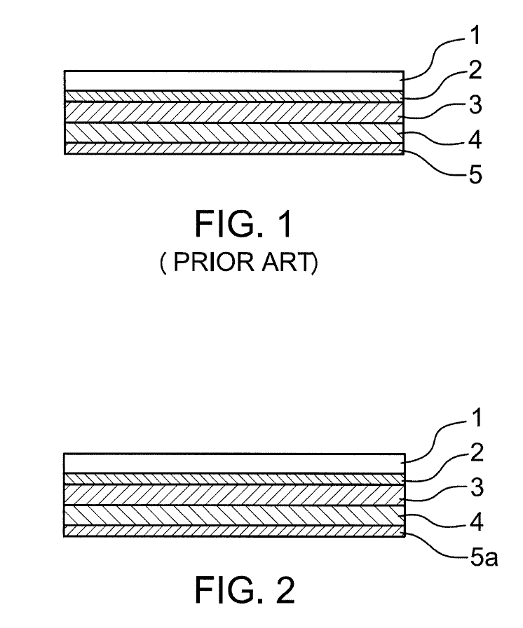

As shown in FIG. 1, a conventional PV module mainly comprises a transparent front layer (typically glass) 1, PV stack 2, an encapsulant (not shown) such as ethylene vinyl acetate (EVA) or polyvinyl butyral (PVB), and a back protection layer mainly including a dielectric layer 3, a barrier layer 4 and a weatherable layer 5.

As shown in FIG. 2, the present invention provides a novel weatherable layer 5a made from acrylate polymer, e.g. films or sheets of polymethylmethacrylate (PMMA) or film formed from acrylic latex emulsion, for the PV module.

The weatherable layer comprises an acrylic-based polymer, which can form, for example, a powder coating of polymethylmethacrylate (PMMA) or a liquid coating of acrylic latex emulsion. PMMA is the most common acrylate polymer. It is transparent to UV radiation, and therefore does not suffer as much from UV degradation as other polymers which absorb UV radiation. PMMA is not prone to hydrolysis. In addition, PMMA materials can have RTI (relative temperature index) of 90° C., as exemplified by PMMA materials such as Acrylite Plus® (Evonik CYRO LLC.). Thus, PMMA materials are suitable for PV applications which need to comply with TUV and UL testing requirements (a polymer with RTI greater than or equal to 90° C. is recommended to satisfy a PV module's long term use).

The weatherable layer of the present invention preferably comprises more than 50% weight acrylic-based polymer (e.g. PMMA), more preferably comprises more than 70% weight acrylic-based polymer and most preferably comprises more than 90% weight acrylic-based polymer. Because acrylic-based polymer is abundant and more cost-effective than fluorinated polymers which have a limited supply and are expensive, it can effectively replace PVF or other equivalent fluorinated polymers in a traditional back protection layer of a PV module.

The weatherable layer of the present invention is easily processed in the manufacture of PV modules. The weatherable layer can be in any form to be applied to protect the PV module, exemplified but not limited to the following forms: film, sheet, dispersion, solvent solution and melt. The weatherable layer may be produced as a sheet or film by known processes, such as extrusion, cell cast, injection molding, compression molding, calendaring, blow molding, and continuous cast. The weatherable layer of the present invention has a thickness of at least 1 micron, more preferably at least 20 microns.

According to one aspect of the present invention, the weatherable layer may contain one or more additives in an effective amount, including but not limited to UV stabilizers—which may be organic stabilizers (for example, hindered amine light stabilizers) or inorganic particles (for example, carbon black) for permanent UV protection; plasticizers (for example, phthalates and esters); fillers (for example talc); coloring agents or pigments (such as titanium dioxide); antioxidants (such as phenolic compounds or phosphites); processing aids and dispersing aids (for example, Montan wax).

The weatherable layer may be transparent or opaque, with opaque being preferred. The weatherable layer may be colored or un-colored, with colored being preferred. More preferably, the weatherable layer is black. The weatherable layer of the present invention may contain carbon black to absorb UV radiation or titanium dioxide to reflect radiation.

By applying the present invention, the PV module will be excellent in weatherability, outdoor temperature resistance, and chemical resistance. Therefore, the PV module can maintain high performance for a long term.

### EXAMPLE

An example of the present invention will be described. The example illustrates a preferable embodiment of the present invention, and the present invention is not limited to the example.

### Example 1

The PV module which can be illustrated by FIG. 2, comprises a transparent front layer (glass) 1, PV cell such as thin-film amorphous Silicon (a-Si) structure of TCO/p-i-n/TCO/metal as PV stack 2, ethylene vinyl acetate (EVA) as an encapsulant (not shown), PET as a dielectric layer 3, aluminum foil as a barrier layer 4 and a weatherable layer 5a.

The weatherable layer 5a may be formed from a typical water-based acrylic latex emulsion coating, such as, Aquapro Brushing Laquer (Camelpaint co. ltd.) on an aluminum foil. The acrylic latex emulsion was applied manually by brushing on the surface of the aluminum foil in a manner such that one full side of the aluminum foil is fully covered by the latex emulsion. The aluminum foil and the latex emulsion were then dried at room temperature for about 4 hours to form a dry coating on the aluminum. The thickness of the acrylic polymer coating was approximately 10 to 40 microns.

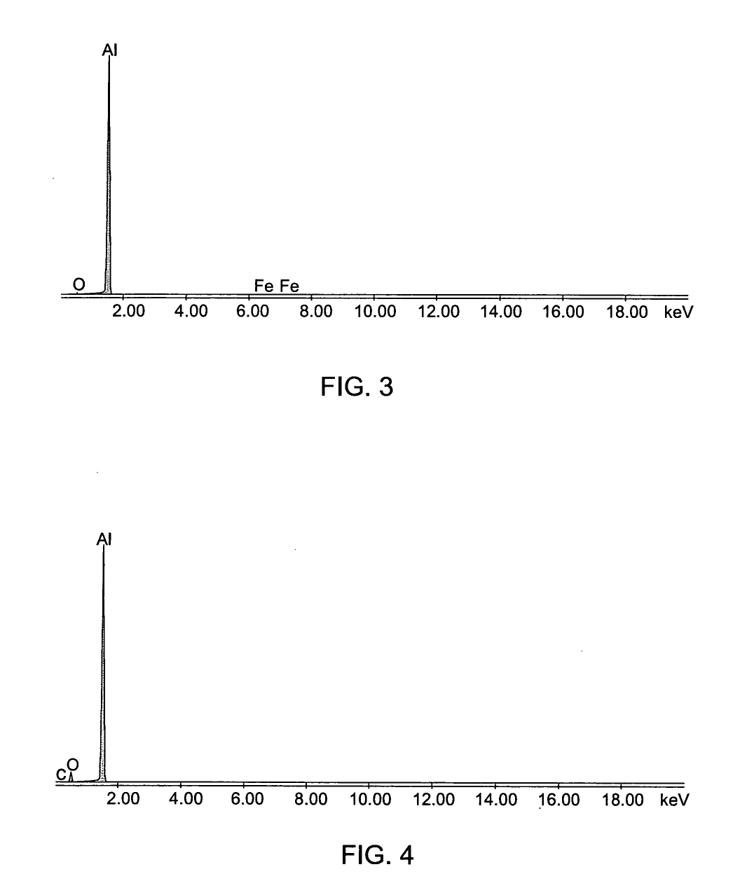

One uncoated and one coated aluminum foil were immersed in 80 degree Celsius water for 48 hours. Energy-dispersive X-ray spectroscopy was then used to quantify the corrosion condition of the foil. The results shown in FIGS. 3 and 4 indicated that new oxygen peak was not found in the spectrum of the coated aluminum foil but was found in the uncoated aluminum foil. Hence, the aluminum foil was protected by the coating.

What is claimed is:

1. A photovoltaic (PV) module comprising a weatherable layer, wherein the weatherable layer comprises acrylic-based polymer.

2. The PV module of claim 1, wherein acrylic-based polymer of the weatherable layer is more than 50 weight % of the weatherable layer.

3. The PV module of claim 2, wherein acrylic-based polymer of the weatherable layer is more than 70 weight % of the weatherable layer.

4. The PV module of claim 2, wherein acrylic-based polymer of the weatherable layer is more than 90 weight % of the weatherable layer.

5. The PV module of claim 1, wherein the weatherable layer is opaque, colored or black.

6. The PV module of claim 1, wherein the weatherable layer is at least 1 micron.

7. The PV module of claim 6, wherein the weatherable layer is at least 20 micron.

8. The PV module of claim 1, wherein the weatherable layer comprises carbon black or titanium oxide.

9. The PV module of claim 1, wherein the acrylic-based polymer is in a form of a powder coating of polymethylmethacrylate (PMMA) or a liquid coating of acrylic latex emulsion.

10. The PV module of claim 1, wherein the acrylic-based polymer is PMMA.
